(19) United States
(12) Patent Application Publication
(10) Pub. No.: US 2026/0032977 A1
(43) Pub. Date: Jan. 29, 2026

(54) SEMICONDUCTOR STRUCTURES AND METHODS OF FORMING SAME

(71) Applicant: Taiwan Semiconductor Manufacturing Company, Ltd., Hsin-Chu (TW)

(72) Inventor: Tzu-Ging LIN, Kaohsiung City (TW)

(21) Appl. No.: 18/956,530

(22) Filed: Nov. 22, 2024

Related U.S. Application Data
(60) Provisional application No. 63/675,168, filed on Jul. 24, 2024.

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 62/151; H10D 64/018; H10D 84/013; H10D 84/038; H10D 84/83

(57) ABSTRACT

A method includes forming a fin-shaped structure disposed over a substrate, the fin-shaped structure including a stack of alternating channel layers and sacrificial layers, forming a dummy gate structure over a channel region of the fin-shaped structure, forming a source/drain recess in a source/drain region of the fin-shaped structure, selectively and partially recessing the sacrificial layers to form inner spacer recesses among the channel layers, forming inner spacer features in the inner spacer recesses, forming a source/drain feature in the source/drain recess, removing the dummy gate structure to form a gate trench, selectively removing the sacrificial layers to form an opening, performing an etching process to remove a portion of the channel layers and a portion of the inner spacer features, thereby enlarging the gate trench and the opening, and forming a gate structure in the enlarged gate trench and the enlarged opening.

### PRIORITY DATA

This application claims priority to U.S. Provisional Patent Application No. 63/675,168, filed Jul. 24, 2024, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides.

However, despite having many desirable features, multi-gate device fabrication has continued to face challenges as a result of the ongoing scaling down of semiconductor IC dimensions. Thus, existing techniques have not proved entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIGS. 2, 3, 4, 5, 6, 7, 8, 9, 10A, 10B, 11, 12A, 12B, 13, 14, 15A, 15B, 15C, 15D, 15E, 16, 17A, 17B, 17C, 17D, 17E, and 17F illustrate fragmentary cross-sectional views of an exemplary semiconductor structure during various fabrication stages in the method of FIG. 1, according to one or more aspects of the present disclosure.

FIG. 18 illustrates a flowchart of a method for forming a semiconductor structure, according to one or more aspects of the present disclosure.

FIGS. 19, 20, 21, 22A, 22B, 23, 24A, 24B, and 25 illustrate fragmentary cross-sectional views of an exemplary semiconductor structure during various fabrication stages in the method of FIG. 18, according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

GAA transistors may also be referred to as nanosheet transistors or nanowire transistors. They can be either n-type or p-type. GAA transistors may have channel regions disposed in nanowire channel members, bar-shaped channel members, nanosheet channel members, nanostructure channel members, bridge-shaped channel members, and/or other suitable channel configurations. In some existing technologies, the formation of GAA transistors includes forming a number of channel layers interleaved by a number of sacrificial layers and performing a channel release process to selectively remove the sacrificial layers to release the channel layers as channel members. The channel layers and the sacrificial layers may include different compositions. However, components of the sacrificial layers may diffuse into the channel layers to form an interdiffusion region. The interdiffusion region may not be fully removed during the channel release process, thereby disadvantageously impacting overall performance of the GAA transistors. While existing techniques are generally adequate for their intended purposes, they are not satisfactory in all aspects.

The present disclosure provides methods for forming a semiconductor device such as a GAA transistor. In an example process, a fin-shaped structure with channel layers and sacrificial layers is formed over a substrate. After formation of a dummy gate stack over a channel region of the fin-shaped structure, at least one gate spacer is formed over the dummy gate stack. Source/drain regions of the fin-shaped structure are recessed. The sacrificial layers are partially and selectively recessed to form inner spacer recesses, and inner spacer features are formed in the inner spacer recesses. After source/drain features are formed in the source/drain regions, the dummy gate stack is removed. Then the sacrificial layers are selectively removed to release the channel layers as channel members. Additional etching processes are performed to remove a portion including interdiffusion regions (e.g., regions where components of the sacrificial layers are diffused into) of the channel layers and/or a portion of the inner spacer features. In some other examples, after recessing the source/drain regions, the sacrificial layers are replaced by a dummy layer, which is then partially and selectively recessed to form the inner spacer recesses. After the dummy gate stack is removed, the dummy layer is selectively removed. Additional etching processes are performed to remove a portion of the channel layers and/or a portion of the inner spacer features. Further processes are then performed to finish the fabrication of the GAA transistor. By performing the additional etching processes, interdiffusion regions in the channel members are removed, heights and surfaces of the channel members may be modified (e.g., reduced, smoothened, rounded), and uniformity of dimensions of the channel members may be improved, thus overall performance of the semiconductor device may be improved.

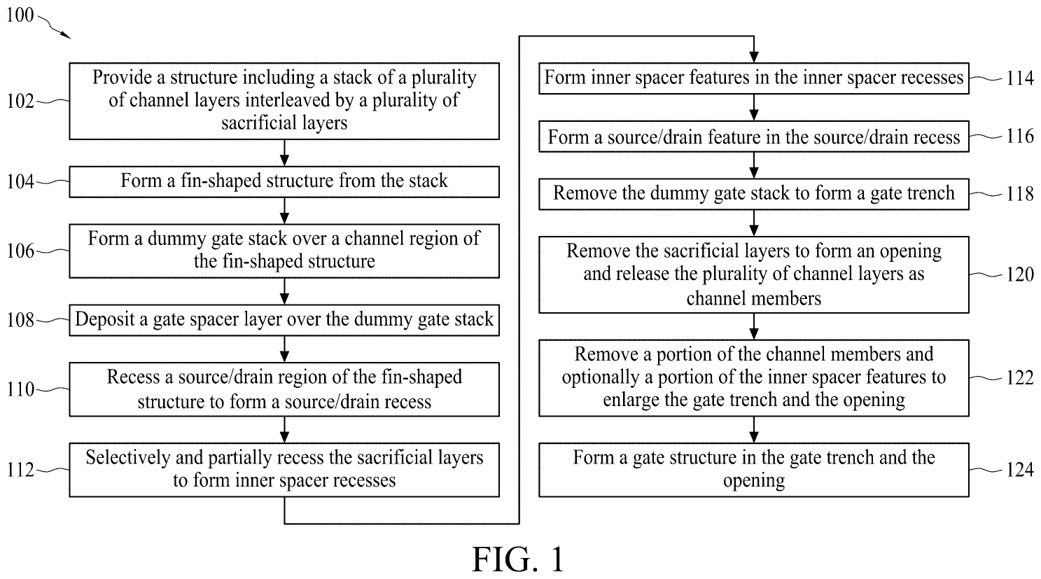

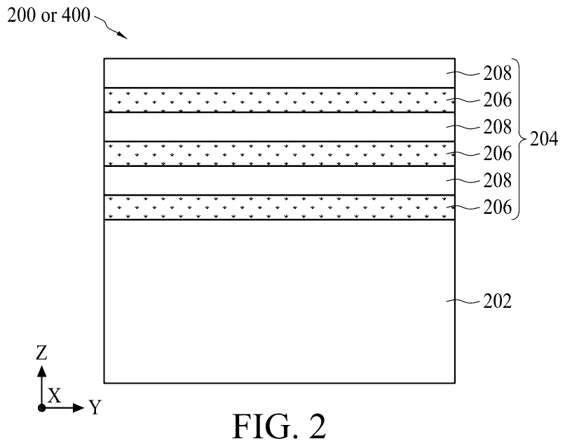

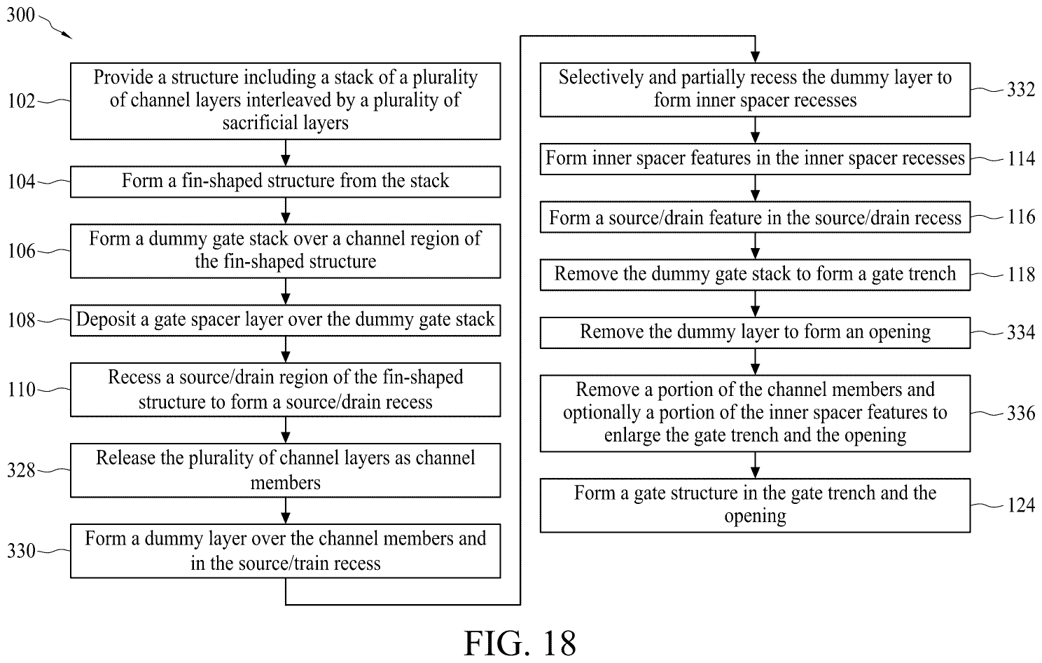

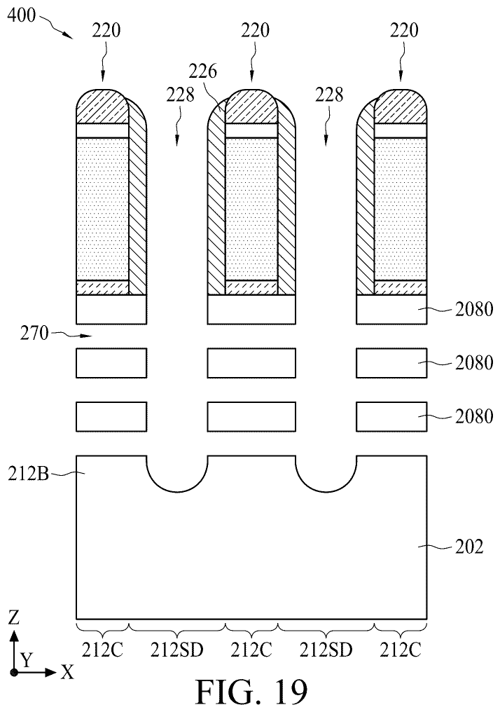

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-17F. FIGS. 2-17F are fragmentary cross-sectional views of a structure 200 at different stages of fabrication according to embodiments of method 100 in FIG. 1. FIG. 18 is a flowchart illustrating method 300 of forming a semiconductor structure according to embodiments of the present disclosure. Method 300 is described below in conjunction with FIGS. 19-25, which are fragmentary cross-sectional views of a structure 400 at different stages of fabrication according to embodiments of method 300 in FIG. 18. Method 100 and method 300 are merely examples and are not intended to limit the present disclosure to what is explicitly illustrated in method 100 and method 300. Additional steps can be provided before, during and after method 100 (or method 300), and some steps described can be replaced, eliminated, or moved around for additional embodiments of method 100 (or method 300). Not all steps are described herein in detail for reasons of simplicity. Because the structure 200 (or 400) will be fabricated into a semiconductor structure or a semiconductor device, the structure 200 (or 400) may be referred to herein as a semiconductor structure 200 (or 400) or a semiconductor device 200 (or 400) as the context requires. For avoidance of doubts, the X, Y and Z directions in FIGS. 2-17F and 19-25 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Further, the semiconductor structures disclosed herein may include various other devices and features, such as other types of devices including additional transistors, bipolar junction transistors, resistors, capacitors, inductors, diodes, fuses, SRAM and/or other logic circuits, etc., but are simplified for a better understanding of the inventive concepts of the present disclosure. In some embodiments, the exemplary devices include a plurality of semiconductor devices (e.g., transistors), including n-type GAA transistors, p-type GAA transistors, PFETs, NFETs, etc., which may be interconnected.

Referring to FIGS. 1 and 2, method 100 includes a block 102 where a structure 200 is provided. As shown in FIG. 2, the structure 200 includes a substrate 202 and a stack 204 of alternating semiconductor layers formed over the substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channel members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

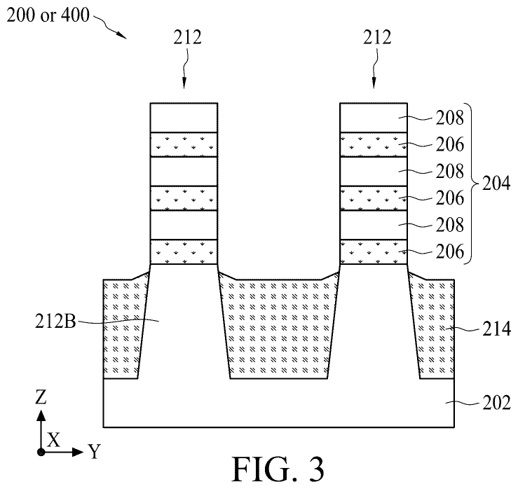

Referring to FIGS. 1 and 3, method 100 includes a block 104 where a fin-shaped structure 212 (also referred to as an active region 212) is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., reactive-ion etching (RIE)), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202. The patterned stack 204, including the sacrificial layers 206 and the channel layers 208, is disposed directly over the base fin structure 212B.

An isolation feature 214 is formed adjacent to the fin-shaped structure 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure 212. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is embedded or buried in the isolation feature 214. In some embodiments, operations at block 104 includes forming a capping layer (not depicted) over top surfaces of the isolation features 214 to protect the isolation features 214 in the following processes. The capping layer may include a nitride, such as silicon nitride, silicon oxynitride, silicon carbide, silicon carbonitride, silicon oxycarbonitride, or the like. The capping layer may be deposited using a suitable process, such as CVD, plasma-enhanced CVD (PECVD), ALD, or the like. The capping layer deposited on the sidewall may be removed by any suitable etch processes, such as a dry etch or wet etch.

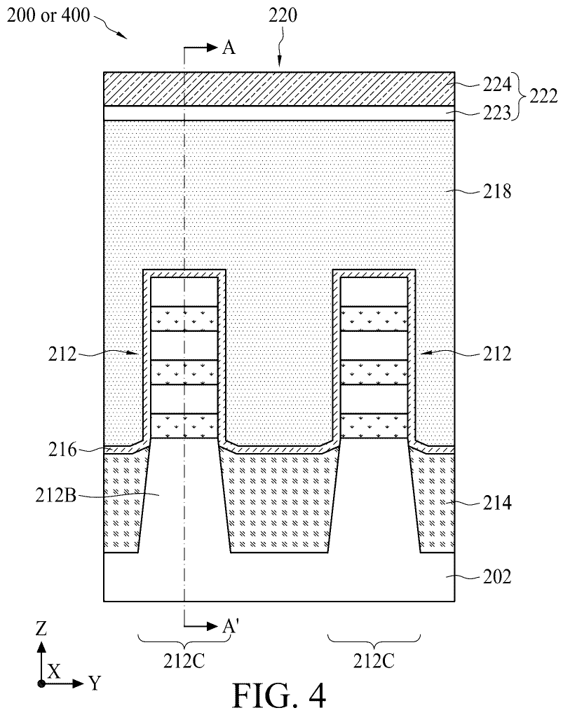

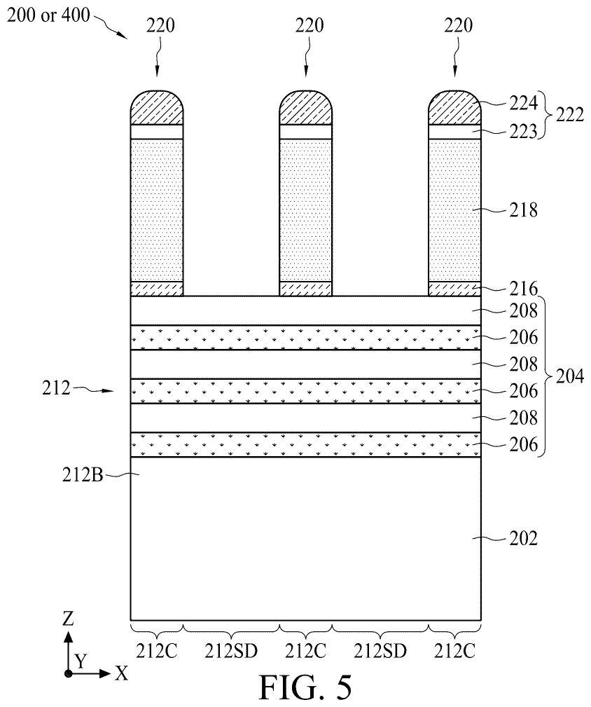

Referring to FIGS. 1, 4, and 5, method 100 includes a block 106 where a dummy gate stack 220 is formed over a channel region 212C of the fin-shaped structure 212. FIG. 5 illustrates a fragmentary cross-section view of the structure 200 taken along line A-A′ as in FIG. 4. In some embodiments, a gate replacement process (or gate-last process) is adopted where the dummy gate stack 220 (shown in FIGS. 4 and 5) serves as a placeholder to undergo various processes and is to be removed and replaced by a functional gate structure. Other processes and configuration are possible. In some embodiments illustrated in FIG. 5, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the structure 200. In some embodiments, the dummy dielectric layer 216 may be formed on the fin-shaped structure 212 using a chemical vapor deposition (CVD) process, an atomic layer deposition (ALD) process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, the dummy gate stack 220 is patterned such that it is only disposed over the channel region 212C, not disposed over the source/drain region 212SD.

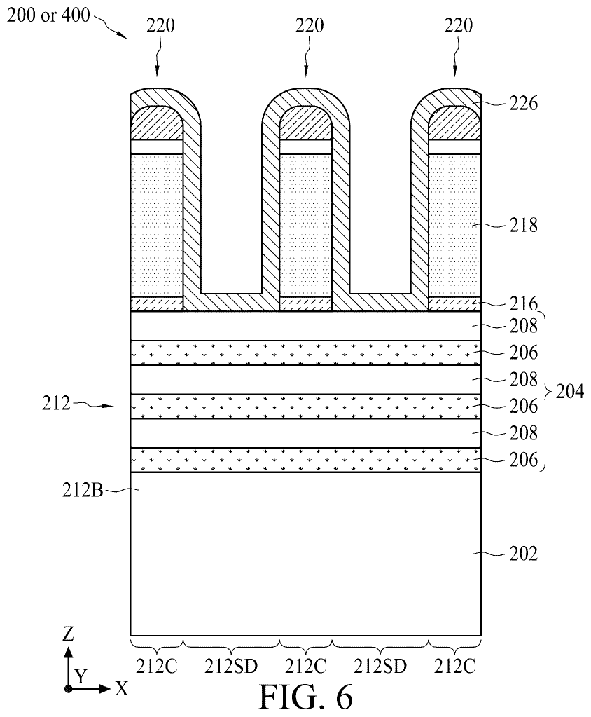

Referring to FIGS. 1 and 6, method 100 includes a block 108 where a gate spacer layer 226 is deposited over the structure 200, including over the dummy gate stack 220. In some embodiments, the gate spacer layer 226 is deposited conformally over the structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

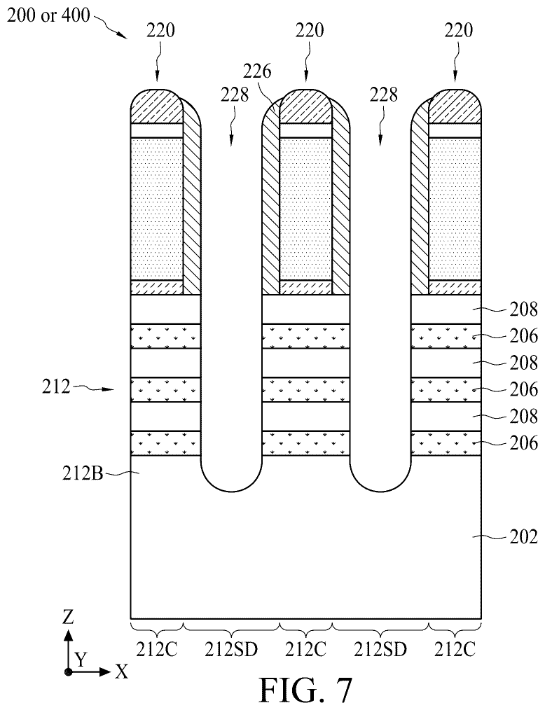

Referring to FIGS. 1 and 7, method 100 includes a block 110 where a source/drain region 212SD of the fin-shaped structure 212 is anisotropically recessed to form a source/drain trench 228. The anisotropic etch may include a dry etch or a suitable etch process that etches the gate spacer layer 226, the source/drain regions 212SD and a portion of the substrate 202 below the source/drain regions 212SD. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 7, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

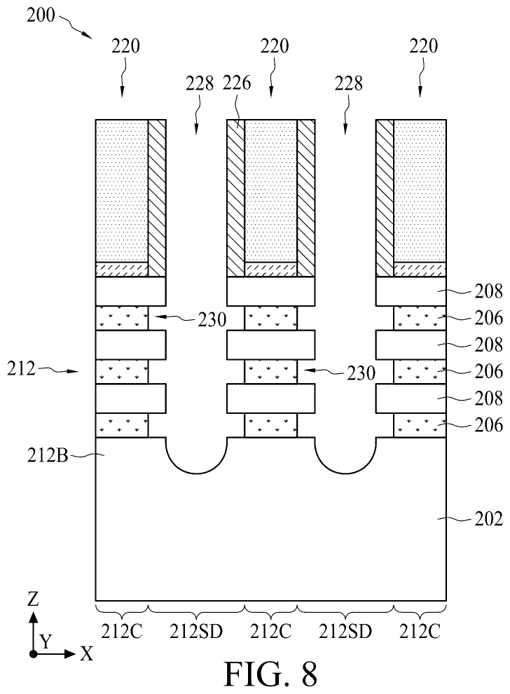

Referring to FIGS. 1 and 8, method 100 includes a block 112 where the sacrificially layers 206 are selectively and partially recessed to form inner spacer recesses 230. As described above, a composition of the channel layers 208 is different from that of the sacrificial layers 206. At block 112, the different compositions allow the sacrificial layers 206 in the stack 204 exposed in the source/drain recesses 228 to be selectively and partially recessed to form inner spacer recesses 230 while the exposed channel layers 208 are substantially unetched. In an embodiment where the channel layers 208 consist essentially of Si and sacrificial layers 206 consist essentially of SiGe, the selective recess of the sacrificial layers 206 may include a SiGe oxidation process followed by a SiGe oxide removal. In those embodiments, the SiGe oxidation process may include use of ozone. In some embodiments, the selective recess may be a selective isotropic etching process (e.g., a selective dry etching process or a selective wet etching process), and the extent the sacrificial layers 206 are recessed is controlled by duration of the etching process. In some embodiments, the selective dry etching process may include use of one or more fluorine-based etchants, such as fluorine gas or hydrofluorocarbons. The inner spacer recesses may extend inward along the X-direction from the source/drain recesses 228. In some embodiments, the selective wet etching process may include a hydro fluoride (HF) or NH₄OH etchant.

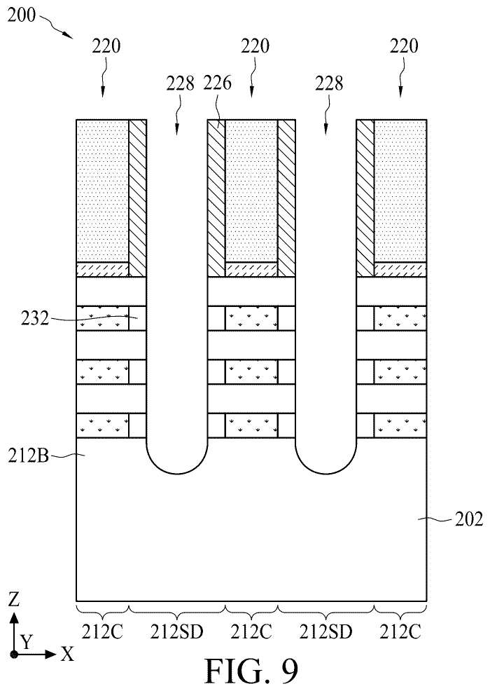

Referring to FIGS. 1 and 9, method 100 includes a block 114 where inner spacer features 232 are formed in the inner spacer recesses 230. While not shown explicitly, operation at block 114 may include deposition of inner spacer material over the structure 200, and etching back the inner spacer material to form the inner spacer features 232 in the inner spacer recesses 230 (shown in FIG. 9). After the inner spacer recesses 230 are formed, an inner spacer material is deposited over the structure 200, including over the inner spacer recesses 230. The inner spacer material may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses 230 as well as over the sidewalls of the channel layers 208 exposed in the source/drain trenches 228. Referring to FIG. 9, the deposited inner spacer material is then etched back to remove the inner spacer material from the sidewalls of the channel layers 208 to form the inner spacer features 232 in the inner spacer recesses 230.

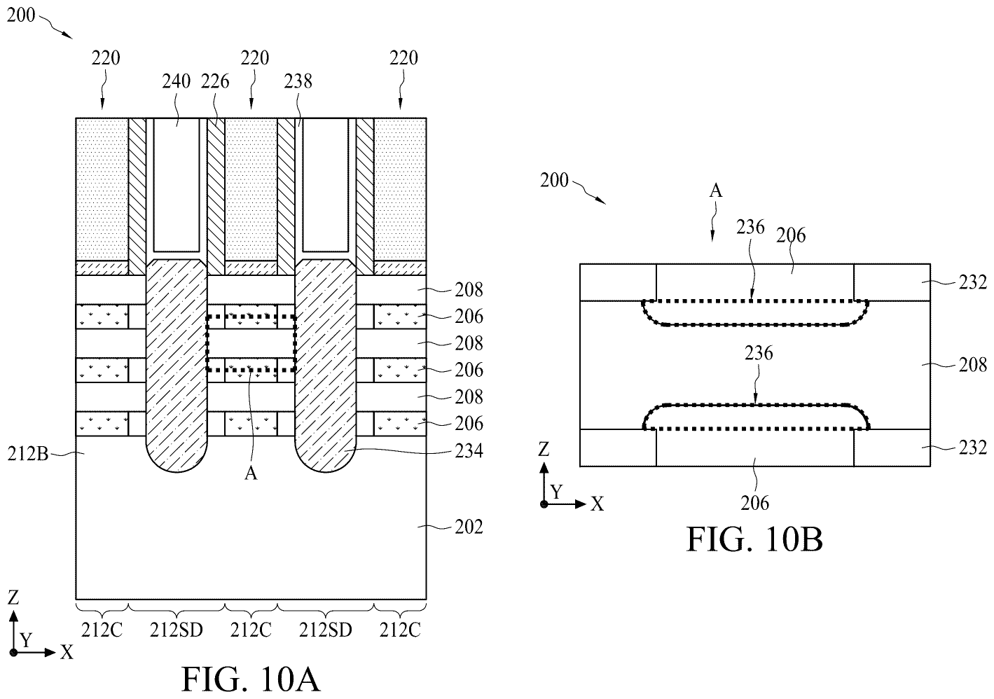

Referring to FIGS. 1 and 10A-10B, method 100 includes a block 116 where a source/drain feature 234 is formed over the source/drain region 212SD. FIG. 10B illustrates an enlarged view of a portion A in FIG. 10A. While not explicitly shown, before any of the epitaxial layers are formed, method 100 may include a cleaning process to clean surfaces of the structure 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide, SPM (a sulfuric peroxide mixture), and/or hydrofluoric acid for oxide removal. The dry clean process may include helium (He) and hydrogen (H₂) treatment. The hydrogen treatment may convert silicon on the surface to silane (SiH₄), which may be pumped out for removal.

Source/drain feature(s) 234 may refer to a source or a drain, individually or collectively dependent upon the context. The source/drain features 234 are coupled to the channel regions 212C. Each of the source/drain features 234 may be epitaxially and selectively formed from exposed semiconductor surfaces by using an epitaxial process, such as vapor phase epitaxy (VPE), ultrahigh vacuum chemical vapor deposition (UHV-CVD), molecular-beam epitaxy (MBE), and/or other suitable processes. Example n-type source/drain features may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Example p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In some embodiments, each of the n-type source/drain features and the p-type source/drain features may include multiple semiconductor layers with different doping concentrations. The n-type source/drain features and the p-type source/drain features may be formed in any suitable sequential orders. One or more annealing processes may be performed to activate the dopants in the source/drain features 234. The annealing processes may include rapid thermal annealing (RTA) and/or laser annealing processes.

In some embodiments, some components in the sacrificial layers 206 may diffuse into surface regions of the adjacent channel layers 208 as depicted in FIG. 10B and surface regions of the adjacent base fin structure 212B. In embodiments where the sacrificial layers 206 include SiGe, the diffused components may include germanium. The surface regions include the diffused components and may be referred to as interdiffusion regions 236. The annealing processes to activate the dopants in the source/drain features 234 as described above may expediate the diffusion of the components and the forming of the interdiffusion regions 236.

Operations at block 116 may further include deposition of a contact etch stop layer (CESL) 238 over the source/drain features 234 and deposition of an interlayer dielectric (ILD) layer 240 over the CESL 238. Referring to FIG. 10A, the CESL 238 is deposited over the structure 200, including over the source/drain feature 234. The CESL 238 may include silicon nitride or aluminum nitride. In some implementations, the CESL 238 may be deposited using CVD or ALD. The ILD layer 240 is then deposited over the CESL 238. In some embodiments, the ILD layer 240 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 240 may be deposited using CVD, FCVD, spin-on coating, or a suitable deposition technique. In some embodiments, operations at block 116 further includes forming a protection layer over the ILD layer 240 and between the CESL 238. The capping layer may be formed by recessing the ILD layer 240 using a dry or wet etching process and then depositing a dielectric material over the structure 200. The dielectric material may include one or more materials such as silicon nitride, silicon oxynitride, or the like. After the deposition of the ILD layer 240 and/or the protection layer, the structure 200 may be planarized by a planarization process (e.g., a chemical mechanical planarization (CMP) or grinding process) to remove excess insulating material from over the structure 200. The remaining dielectric material over the ILD layer 240 forms the protection layer. The protection layer may protect the ILD layer 240 in the following processes. The planarization process may expose the dummy gate stack 220. Exposure of the dummy gate stack 220 allows the removal of the dummy gate stack 220.

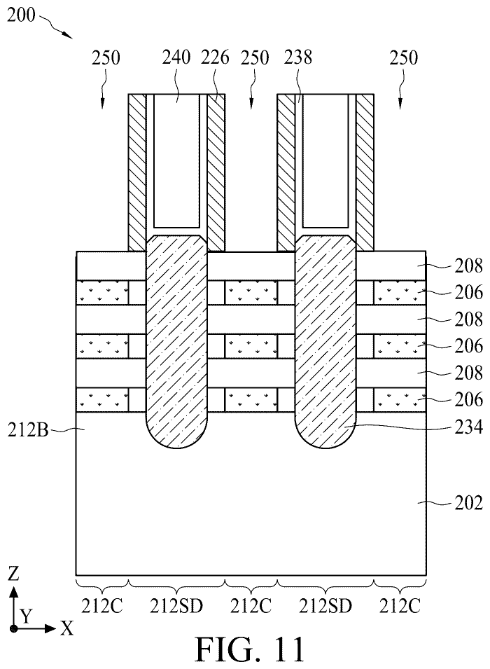

Referring to FIGS. 1 and 11, method 100 includes a block 118 where the dummy gate stack 220 is removed to form a gate trench 250. The removal of the dummy gate stack 220 may include one or more etching processes that are selective to the material of the dummy gate stack 220. For example, the removal of the dummy gate stack 220 may be performed using a selective wet etch, a selective dry etch, or a combination thereof that is selective to the dummy gate stack 220. The removal of the dummy gate stack 220 creates gate trenches 250. The gate trenches 250 expose a top surface of the topmost channel layer 208 and sidewalls of the channel layers 208 and the sacrificial layers 206. In other words, the channel layers 208 and the sacrificial layers 206 are exposed at least on two sidewalls in the gate trenches 250. Additionally, the gate trenches 250 also expose top surfaces of the isolation features 214.

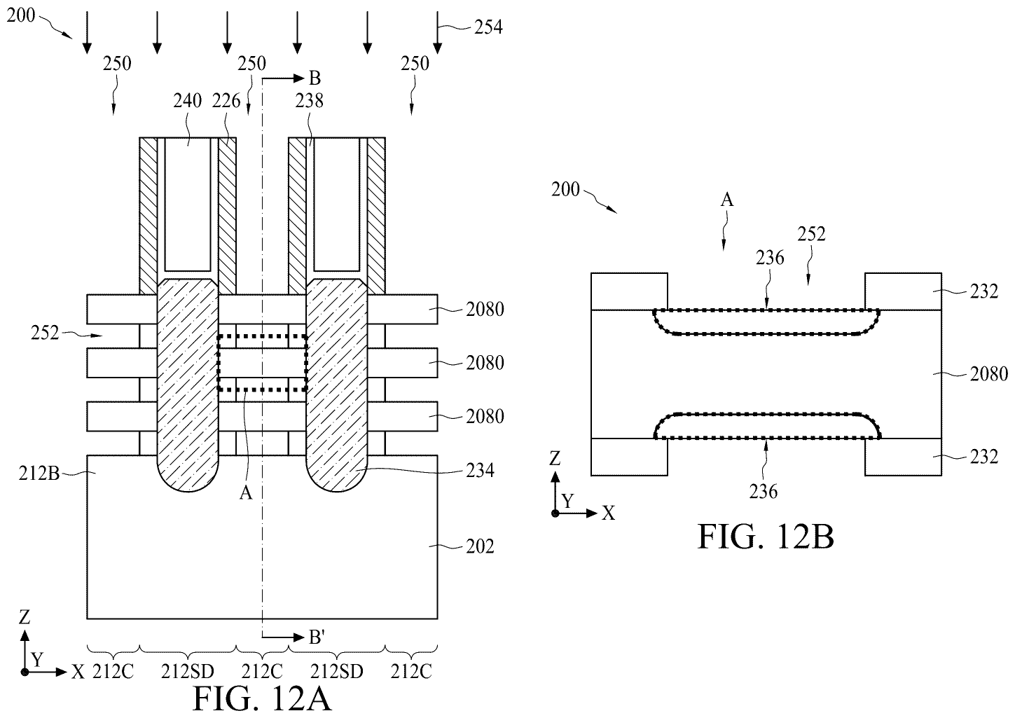

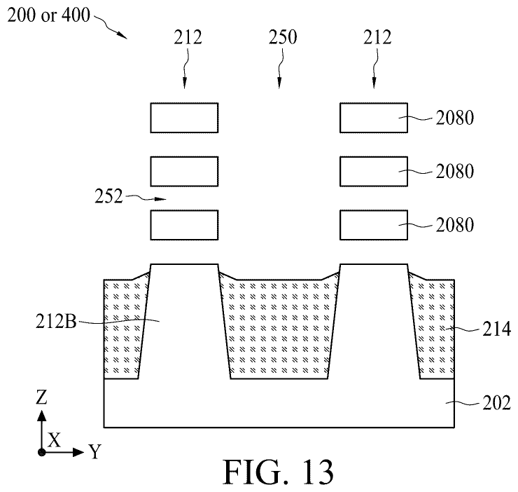

Referring to FIGS. 1 and 12A-13, method 100 includes a block 120 where the sacrificial layers 206 are removed to form openings and the plurality of channel layers 208 in the channel regions 212C are released as channel members 2080. FIG. 12B illustrates an enlarged view of a portion A in FIG. 12A. FIG. 13 illustrates a fragmentary cross-section view of the structure 200 taken along line B-B′ as in FIG. 12A. In the depicted embodiment, a first etching process 254 selectively etches the exposed sacrificial layers 206 with minimal or no etching of the channel layers 208 (including the interdiffusion regions 236). In some embodiments, the etching process 254 has minimal or no etching of the gate spacer layer 226 and the inner spacer features 232. Various etching parameters can be tuned to achieve selective etching of the sacrificial layers 206, such as etchant composition, etching temperature, etching solution concentration, etching time, etching pressure, source power, RF bias voltage, RF bias power, etchant flow rate, other suitable etching parameters, or combinations thereof. For example, an etchant is selected for the etching process 254 that etches the material of the sacrificial layers 206 (e.g., silicon germanium) at a first rate R1 and etches the material of the channel layers 208 (e.g., silicon) at a second rate R2. R1 is greater than R2. A ratio of R1 to R2 (or etch selectivity of the material of the sacrificial layers 206 to the material of the channel layers 208) is greater than about 5:1, alternatively about 10:1 to about 50:1. The etching process 254 may be a dry etching process, a wet etching process, other suitable etching process, or combinations thereof. In some embodiments, a dry etching process (such as an RIE process) utilizes one or more halogen-based etchants (e.g., fluorine-based etchants), such as nitrogen trifluoride (NF₃), chlorine trifluoride (ClF₃), fluorine gas (F₂), hydrofluorocarbons, hydrogen fluoride (HF), or a combination thereof to selectively etch the sacrificial layers 206. In some embodiments, the etchants include F₂ and HF, and a ratio of F₂ to HF is about 0.02 to about 50. The etchant may be dissociated into radicals to enhance their reactivity. In some embodiments, a wet etching process utilizes an etching solution that includes ammonium hydroxide (NH₄OH) and water (H₂O) to selectively etch the sacrificial layers 206. In some embodiments, a chemical vapor phase etching process using hydrochloric acid (HCl) selectively etches the sacrificial layers 206. Upon conclusion of the operations at block 120, the channel members 2080 in the channel regions 212C become suspended over openings 252 left behind by removal of the sacrificial layers 206. The openings 252 are in fluid communication with the gate trench 250.

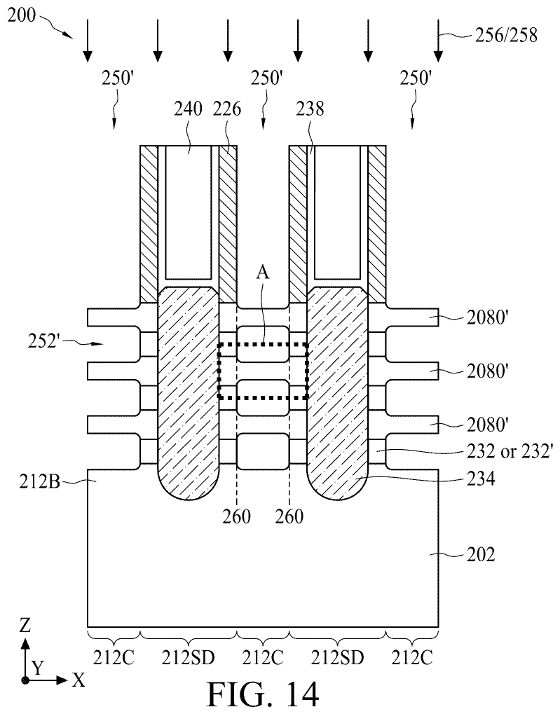

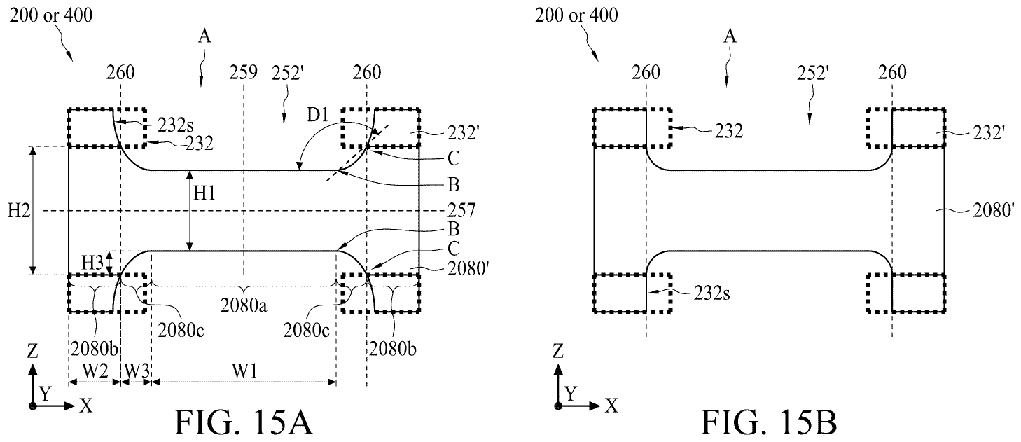

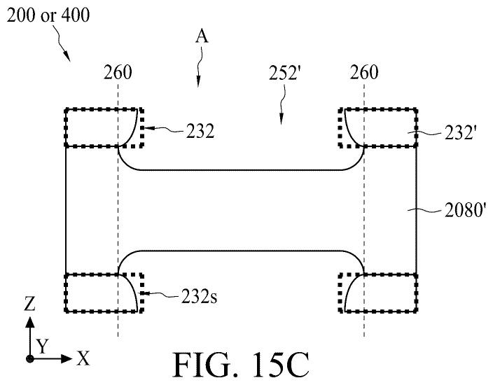

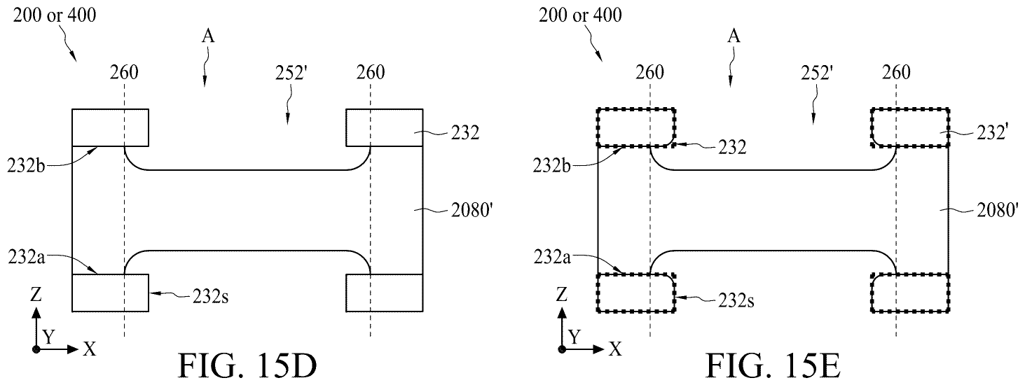

Referring to FIGS. 1 and 14-15E, method 100 includes a block 122 where a portion of the channel members 2080 and the base fin structure 212B, and optionally a portion of the inner spacer features 232 are removed to enlarge the gate trench 250 and the openings 252, thereby forming an enlarged gate trench 250′ and enlarged openings 252′. FIGS. 15A and 15B-15E illustrate an enlarged view and alternative enlarged views of a portion A in FIG. 14, respectively. For clarity, the channel members 2080 are labeled as 2080′ after the portion of the channel members 2080 is removed, and the inner spacer features 232 are labeled as 232′ after the portion of the inner spacer features 232 is removed. Operations at block 122 may include a second etching process 256 to remove the portion of the channel members 2080. In some embodiments (e.g, in FIGS. 15A-15C and 15E), operations at block 122 further includes a third etching process 258 to remove the portion of the inner spacer features 232. In some other embodiments, such as depicted in FIG. 15D, the third etching process 258 is omitted.

The etching process 256 trim (i.e., remove a portion of) the channel members 2080 and the base fin structure 212B exposed in the gate trench 250 and the openings 252. The etching process 256 may include selective dry etch, selective wet etch, or other selective etch processes. In some embodiments, the etching process 256 may be a selective isotropic dry etching process that selectively etches a portion of the channel members 2080 and the base fin structure 212B. In some embodiments, the portion of the channel members 2080 and the base fin structure 212B includes the interdiffusion regions 236 and optionally additional portions that includes essentially (e.g., greater than 95% of) components of the channel members 2080 (e.g., silicon). Various etching parameters can be tuned to achieve the target profiles of the channel members 2080 as described below, such as etchant composition, etching temperature, etching solution concentration, etching time, etching pressure, source power, RF bias voltage, RF bias power, etchant flow rate, byproduct evaporation rate, other suitable etching parameters, or combinations thereof. In an embodiment, the selective dry etching process may include use of one or more halogen-based etchants (e.g., fluorine-based etchants), such as nitrogen trifluoride (NF₃), chlorine trifluoride (ClF₃), fluorine gas (F₂), hydrofluorocarbons, hydrogen fluoride (HF), or a combination thereof. The etchants may be dissociated into radicals to enhance their reactivity. For example, an etchant is selected for the etching process 256 that etches the material of the sacrificial layers 206 (e.g., silicon germanium) at a third rate R3 and etches the material of the channel layers 208 (e.g., silicon) at a fourth rate R4. A ratio of R3 to R4 (or etch selectivity of the material of the sacrificial layers 206 to the material of the channel layers 2080) is about 3:1 to about 1:3.

In some embodiments, the second etching process 256 is different from the first etching process 254. For example, the first etching process 254 is a wet etching process and the second etching process 256 is a dry etching process. For example, the etchant of the second etching process 256 is different from the etchant of the first etching process 254 in composition. In some embodiments, the etchant of the second etching process 256 includes F₂ and HF. A ratio of F₂ to HF in the etchant of the second etching process 256 may be greater than the ratio of F₂ to HF in the etchant of the first etching process 254. In some embodiments, the ratio of F₂ to HF in the etchant of the second etching process 256 changes (e.g., reduces) during the second etching process 256. For example, the second etching process 256 may include a first step and a second step after the first step. The ratio of F₂ to HF in the etchant of the first step may be greater than the ratio of F₂ to HF in the etchant of the first etching process 254. The ratio of F₂ to HF in the etchant of the second step may be less than the ratio of F₂ to HF in the etchant of the first step. The ratio of F₂ to HF in the etchant of the second step may be less than the ratio of F₂ to HF in the etchant of the first etching process 254. The lower ratio of F₂ to HF in the etchant of the second step may reduce surface roughness of the channel members 2080′. In some embodiments, the ratio of R3 to R4 is less than the ratio of R1 to R2. In some embodiments, evaporation rate of byproducts (e.g., silicon halides (SiX₄, X is halogen), germanium tetrahalide (GeX₄, X is halogen), germanium hydride (GeH₄)) in the etching process 256 is greater than evaporation rate of byproducts (e.g., SiX₄, GeX₄, GeH₄) in the etching process 254. The evaporation rate of GeX₄ in the etching process 256 may be greater than the evaporation rate of GeX₄ in the etching process 254. The second etching process 256 may be at a higher temperature and a lower pressure compared to the first etching process 254. In some embodiments, the etching process 254 is performed at a first chamber, the etching process 256 is performed at a second chamber different from the first chamber. The etching process 256 may reduce surface roughness of the channel members 2080. In other words, the surfaces of the channel members 2080′ upon completion of the etching process 256 are smoother than the surfaces of the channel members 2080 upon completion of the etching process 254.

Upon completion of the second etching process 256, the channel members 2080′ each have a dumbbell shape in the cross-sectional view as in FIGS. 14-15E. It is noted that because the second etching process 256 also enlarges the gate trench 250, the topmost channel member 2080′ is similar to the channel members 2080′ therebelow. Top surfaces of the base fin structure 212B have similar profiles as top surfaces of the channel members 2080′ thereabove. Referring to FIG. 15A, each of the channel members 2080′ may be symmetric with respect to a horizontal center line 257 and a vertical center line 259 thereof. The channel members 2080′ may each include a middle portion 2080a, two end portions 2080b, and two joint portions 2080c. The middle portion 2080a has a height Hl along the Z-direction and a width W1 along the X-direction. H1 may be about 4 nm to about 8 nm, alternatively about 5 nm to about 7 nm, and W1 may be about 10 nm to about 40 nm. The end portions 2080b each have a height H2 along the Z-direction and a width W2 along the X-direction. H2 may be about 7 nm to about 12 nm, alternatively about 7 nm to about 9 nm. In some embodiments, a ratio of H1 to H2 may be about 0.5 to about 0.9, alternatively about 0.6 to about 0.8. A ratio of W2 to W1 may be about 0.02 to about 0.5. In some embodiments, the middle portion 2080a and the end portions 2080b have straight or substantially straight top and bottom surfaces. The bottom (or top) surface of the end portion 2080b and the adjacent bottom (or top) surface of the middle portion 2080a may have a vertical distance H3 as depicted. The joint portions 2080c each have a width W3 along the X-direction. W3 may be less than W2 and a ratio of W3 to W2 may be about 0.1 to about 0.8. A ratio of H3 to W3 may be about 0.5 to about 2. In some embodiments, the joint portions 2080c each have a curved (e.g., concaved) top surface and a curved (e.g., concaved) bottom surface. The curved top (or bottom) surface of the joint portion 2080c may have two end points (e.g., inner end point B and outer end point C) in the cross-sectional view. An angle DI between a top (or bottom) surface of the middle portion 2080a and a line through the two end points (e.g., B and C) as depicted in FIG. 15A may be greater than 90 degrees. In some embodiments, D1 is about 110 degrees to about 150 degrees. The curved profile of the joint portions 2080c may increase electrical fields of the adjacent source/drain feature 234. The channel members 2080′ in the alternative enlarged views as in FIGS. 15B-15E may be similar as described in FIG. 15A.

Upon completion of the second etching process 256, as depicted in FIGS. 14-15E, a virtual line 260 through the outer end points C on one side of the channel members 2080 align with a sidewall of the gate spacer later 226 on the one side. Such alignments may increase the performance of the structure 200. Channel dimensions (e.g., lengths along the X-direction and heights along the Z-direction) and profiles are identical among the channel members 2080′, which may improve the performance of the structure 200. In addition, the interdiffusion regions 236 are removed, threshold voltage (Vt) shift caused by impurities in the interdiffusion regions 236 are mitigated.

In some embodiments, the third etching process 258 is performed to remove the portion of the inner spacer features 232, thereby modifying profiles of the inner spacer features 232. Upon completion of the third etching process 258, the inner spacer features 232′ may have various shapes in the cross-sectional view as in FIGS. 15A-15C and 15E. For comparison purpose, embodiments represented by FIG. 15D where the third etching process 258 is omitted are described here together. The dashed rectangles show the profiles of the inner spacer features 232 before the second etching process 258. The inner spacer feature 232′ may have a sidewall 232s exposed to the enlarged opening 252′. In some embodiments, the sidewall 232s intersects with the channel member 2080 on the virtual line 260 as in FIGS. 15A-15C. The sidewall 232s may have a concaved profile (as in FIG. 15A), a straight profile (as in FIG. 15B), or a convex profile (as in FIG. 15C). In some other embodiments, top surfaces 232a and bottom surfaces 232b of the inner spacer features 232′ (or 232) extend beyond the virtual lines 260 toward the enlarged openings 252′ as in FIGS. 15D and 15E. In such embodiments, the inner spacer features 232 may have sharp corners as in FIG. 15D, or the inner spacer features 232′ may have rounded corners as in FIG. 15E. The various profiles of the inner spacer features 232′ (or 232) fulfill different functions and/or designs, and the inner spacer features 232′ (or 232) with designed shape may result in inner portions of a gate structures (to be described below) of designed profiles, which may improve the performance of the structure 200.

In some embodiments, the etching process 258 selectively etches the exposed inner spacer features 232 with minimal or no etching of the channel members 2080 and the base fin structure 212B, the gate spacer layer 226, the CESL layer 238, and the ILD layer 240. An etch selectivity of the inner spacer features 232 over the channel members 2080′ may be greater than about 10:1. The etching process 258 may include selective dry etch, selective wet etch, or other selective etch processes. In some embodiments, the etching process 258 includes a wet etch process using a suitable etchant such as dilute hydrofluoric (dHF) acid. The wet etch process may be a timed process. In some embodiments, the etching process 258 includes a dry etch process using a suitable etchant such as a chlorine-containing gas (e.g., Cl₂, SiCl₄, BCl₃, other chlorine-containing gases, or combinations thereof), a fluorine-containing gas (e.g., CF₄, SF₆, CH₂F₂, CHF₃, C₂F₆, other fluorine-containing etchants, or combinations thereof), a bromine-containing gas (e.g., HBr, other bromine-containing etchants, or combinations thereof), O₂, N₂, H₂, Ar, other suitable gases, or combinations thereof. The choice of etchant component(s) is not limited in the present embodiments and may depend upon the specific composition of the inner spacer features 232.

Various etching parameters can be tuned to achieve the target profiles of the inner spacers 232′ as described above, such as etchant composition, etching temperature, etching solution concentration, etching time, etching pressure, source power, RF bias voltage, RF bias power, etchant flow rate, byproduct evaporation rate, other suitable etching parameters, or combinations thereof. In some embodiments, the third etching process 258 implements both isotropic and anisotropic etching processes, and a ratio R(i/a) of the extent of isotropic etching to the extent of anisotropic etching may be adjusted to achieve various profiles of the inner spacer features 232′. For example, R(i/a) of the embodiments represented by FIGS. 15C and 15E is greater than R(i/a) of the embodiments represented by FIG. 15B, which is greater than R(i/a) of the embodiments represented by FIG. 15A. Time duration of the third etching process 258 of the embodiments represented by FIG. 15E may be less than time duration of the third etching process 258 of the embodiments represented by FIG. 15C. In some embodiments, R(i/a) may be changed dynamically during the etching process to form different profiles. For example, R(i/a) may start at a relatively high value, and then decrease in the etching process 258 in order to form the profile as depicted in FIG. 15C rather than the profiles as depicted in FIGS. 15A or 15B.

In some embodiments, the third etching process 258 is different from the first etching process 254 and the second etching process 256. The etchant of the third etching process 258 may be different from the etchant of the second etching process 256 and the etchant of the first etching process 254 in composition. The temperature of the third etching process 258 may be higher than the temperature of the first etching process 254 and lower than the temperature of the second etching process 256. The pressure of the third etching process may be lower than the pressure of the first etching process 254 and the pressure of the second etching process 256. In some embodiments, before the third etching process 258, a cooling process is performed where the structure is cooled from previous processes (e.g., the second etching process 256), and the temperature of the cooling process is lower than the temperature of the third etching process 258. For the inners spacers 232 having different compositions, operating conditions (e.g., temperature, pressure) of the third etching process 258 may be different from described above.

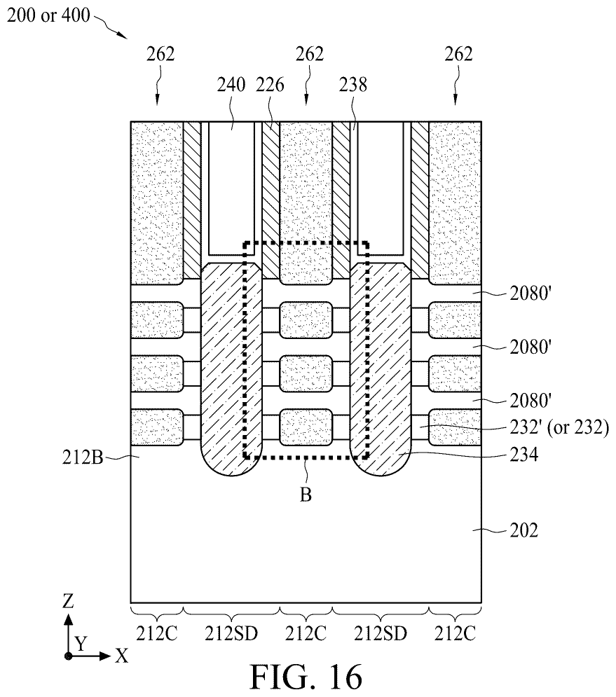

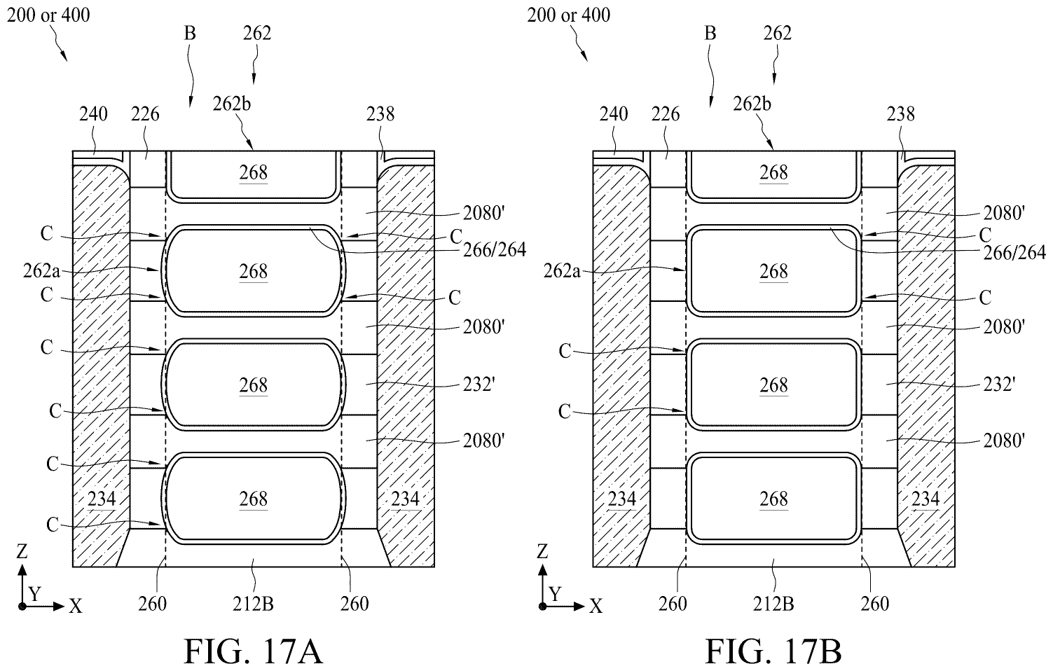

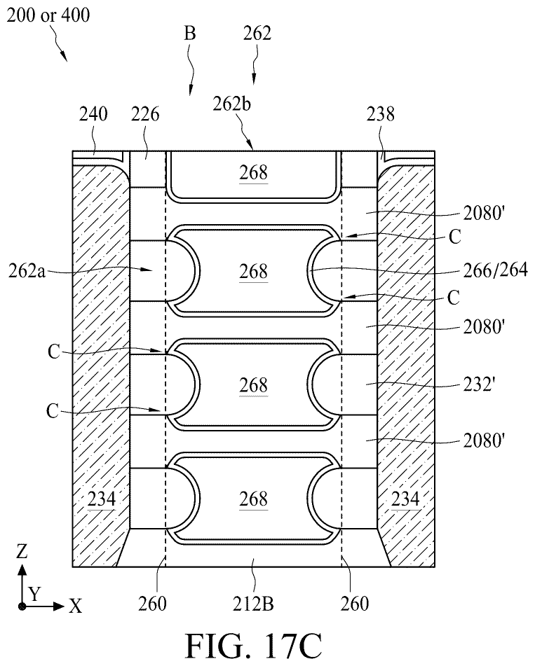

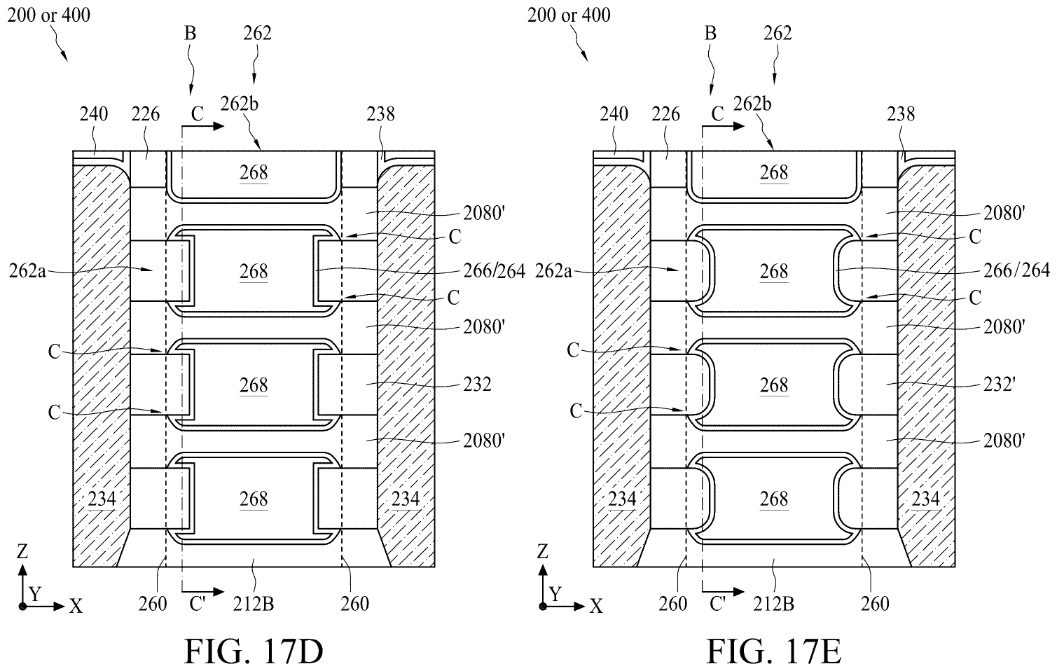

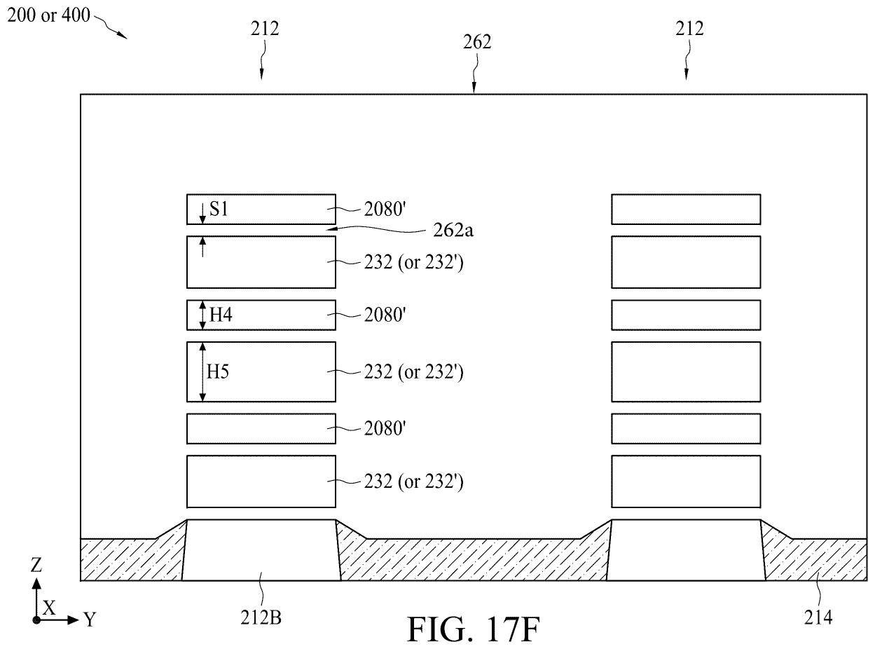

Referring to FIGS. 1 and 16-17F, method 100 includes a block 124 where a gate structure 262 is formed to wrap around each of the channel members 2080′. FIGS. 17A and 17B-17E illustrate an enlarged view and alternative enlarged views of a portion B in FIG. 16. FIG. 17F illustrates a fragmentary cross-sectional view of the structure 200 taken along line C-C′ as in FIGS. 17D and 17E. As shown in FIGS. 17A-17E, the gate structure 262 includes an interfacial layer 264 interfacing the channel members 2080′ and the base fin structure 212B in the channel region 212C, a gate dielectric layer 266 over the interfacial layer 264, and a gate electrode layer 268 over the gate dielectric layer 266. The interfacial layer 264 may include a dielectric material such as silicon oxide, hafnium silicate, or silicon oxynitride. The interfacial layer 264 may be formed by chemical oxidation, thermal oxidation, atomic layer deposition (ALD), chemical vapor deposition (CVD), and/or other suitable method. The gate dielectric layer 266 may include a high-k dielectric material, such as hafnium oxide. Alternatively, the gate dielectric layer 266 may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer 266 may be formed by ALD, physical vapor deposition (PVD), CVD, oxidation, and/or other suitable methods.

The gate electrode layer 268 of the gate structure 262 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 268 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 268 may be formed by ALD, PVD, CVD, e-beam evaporation, or other suitable process. In various embodiments, a CMP process may be performed to remove excessive metal, thereby providing a substantially planar top surface of the gate structure.

FIGS. 17A-17E represent resulted structures fabricated from structures represented by FIGS. 15A-15E, respectively. Referring to FIGS. 17A-17E, the gate structure 262 includes inner portions 262a that interpose between the channel members 2080′ in the channel region 212C and a top portion 262b over the inner portions 262a. The top portion 262b and the inner portions 262a track the shapes of the enlarged gate trench 250′ and the enlarged openings 252′ as described above, respectively. The inner portions 262a of a same gate structure 262 may have an identical shape in a cross-sectional view. The inner portion 262a may have a shape such as a racetrack shape as in FIG. 17A, a rectangle with rounded corners as in FIG. 17B, a shape as in FIG. 17C (also referred to as a first type “I” shape), a shape as in FIGS. 17D (also referred to as a second type “I” shape), and a shape as in FIG. 17E (also referred to as a third type “I” shape). As depicted in FIGS. 17A-17E, each inner portion 262a, one of the adjacent inner spacer features 232′ (or 232), and the adjacent channel member 2080′ have an intersection point, which is the outer end point C of the top (or bottom) curved surface of the joint portion 2080c as described above. The vertical line 260 is through the outer end points C on the right side (or left side) of the gate structure 262, and aligns with a sidewall on the right side (or left side) of the top portion 262b of the gate structure 262. Such alignment may increase the performance of the structure 200.

Referring to FIGS. 17D and 17E, line C-C′ is through the inner spacer feature 232 (or 232′), the inner portions 262a, the channel members 2080′, and the base fin structure 212B. Referring to FIG. 17F, in the cross-sectional view, the gate structure 262 wraps around each of the channel members 2080′ and each of the inner spacer features 232 (or 232′). In the cross-sectional view, the channel members 2080′ may have a height H4 greater than H1 and less than H2 described above, and the inner spacer features 232 (or 232′) may have a height H5 greater than H4 described above. A distance S1 between the neighboring channel member 2080′ (or the base fin structure 212B) and inner spacer 232 (or 232′) may be greater than zero and less than H3 described above.

The semiconductor device 200 may undergo further processing to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including semiconductor device 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

Referring to FIGS. 1 and 18, method 300 includes blocks 102-110, 114-118, and 124 as described above in method 100. Method 300 further includes blocks 328-336 to be described below. Referring to FIGS. 18 and 19, after operations at block 110, method 300 includes a block 328 where the plurality of channel layers 208 (shown in FIG. 7) in the channel regions 212C are released as channel members 2080 (shown in FIG. 19). After the formation of the source/drain trench 228, the sacrificial layers 206 interleaving the channel layers 208 in the channel region 212C are selectively removed. The selective removal of the sacrificial layers 206 releases the channel layers 208 (shown in FIG. 7) to form the channel members 2080 shown in FIG. 19. The selective removal of the sacrificial layers 206 forms openings 270 between adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Depending on the design, the channel members 2080 may take form of nanowires, nanosheets, or other nanostructures.

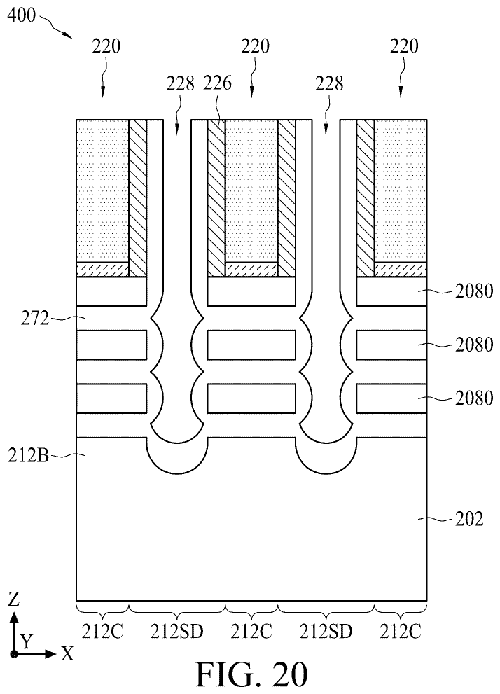

Referring to FIGS. 18 and 20, method 300 includes a block 330 where a dummy layer 272 is deposited around the channel members 2080 and over the source/drain trench 228. The dummy layer 272 may include a dielectric material. The dielectric material may include an oxide, a nitride, a carbide, or a combination thereof. Examples of the dielectric material may include silicon oxide, SiCO, SiN, SiCN, and aluminum oxide (e.g., Al₂O₃). In some embodiments, the dummy layer 272 includes silicon oxide and/or SiN. The dummy layer 272 may have a composition different from a composition of the inner spacer features 232 described above. The dummy layer 272 may be deposited using plasma enhanced chemical vapor deposition (PECVD), an flowable CVD (FCVD), PEALD, ALD, or a rapid thermal oxidation (RTO) process. As shown in FIG. 20, the dummy layer 272 fills the space 270 (shown in FIG. 19) among the channel members 2080 and covers end sidewalls of the channel members 2080. Additionally, the dummy layer 272 is in direct contact with a sidewall of the gate spacer layer 226 and a top surface of the substrate 202 or the base fin structure 212B.

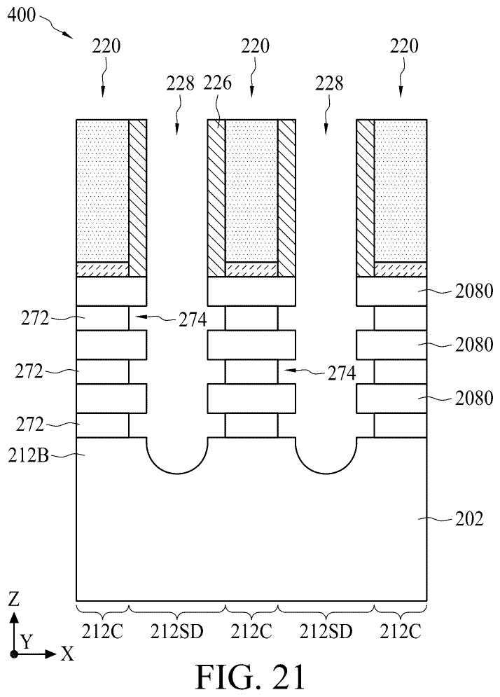

Referring to FIGS. 18 and 21, method 300 includes a block 332 where the dummy layer 272 is selectively and partially recessed to form inner spacer recesses 274 while the gate spacer layer 226, the dummy gate stack 220, the exposed portion of the substrate 202 or the base fin structure 212B, and the channel members 2080 are substantially unetched. In an embodiment where the channel members 2080 consist essentially of silicon (Si) and the dummy layer 272 is formed of silicon oxide, the selective recess of the dummy layer 272 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof. The inner spacer recesses 274 may be of similar dimensions as the inner spacer recesses 230 in FIG. 8.

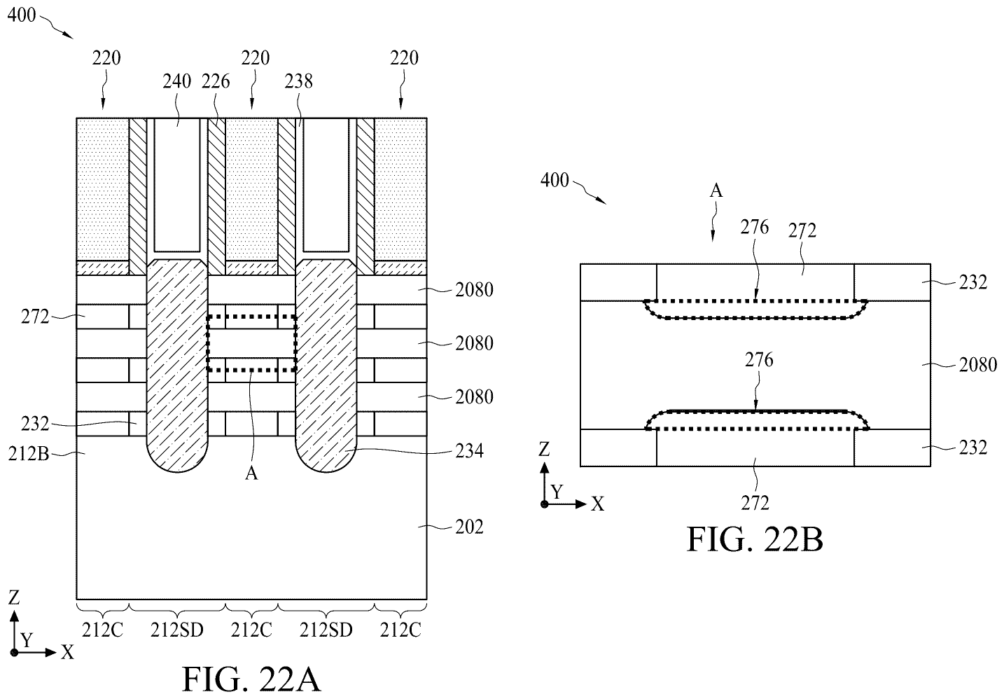

Referring to FIGS. 18 and 22A-22B, after block 332, method 300 proceeds to blocks 114 and 116 where the inner spacer feature 232 and the source/drain features 234 are formed as described above. FIG. 22B illustrates an enlarged view of a portion A in FIG. 22A. Upon completion of operations at block 116, differences from structure 200 in FIGS. 10A-10B include that, in the structure 400, instead of the sacrificial layers 206, the dummy layer 272 is disposed among the channel members 2080 and between the inner spacer features 234. The sacrificial layers 206 described above in method 100 or the dummy layer 272 may be referred to as interposer layer(s). The structure 400 may include interdiffusion regions 276 as depicted. The interdiffusion regions 276 may include components diffused (e.g., during the annealing processes to activate the dopants in the source/drain features 234 as described above) from the dummy layer 272. Because components of the dummy layer 272 diffuse at a relatively low rate into the channel members 2080 compared to the components of the sacrificial layers 206 as described in FIG. 10B, diffusion from the dummy layer 272 into the channel members 2080 is less than the diffusion from the sacrificial layers 206 into the channel layers 208 as described in FIG. 10B. In some embodiments, the interdiffusion regions 276 each have a smaller area than the interdiffusion regions 236.

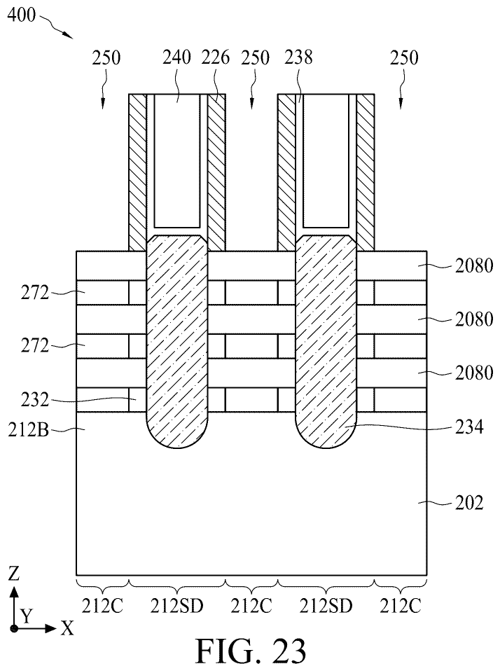

Referring to FIGS. 18 and 23, method 300 includes a block 118 where the dummy gate stack 220 is removed to form a gate trench 250 as described above. A difference from FIG. 11 includes that, in the structure 400, instead of the sacrificial layers 206, the dummy layer 272 is disposed among the channel members 2080 and between the inner spacer features 232.

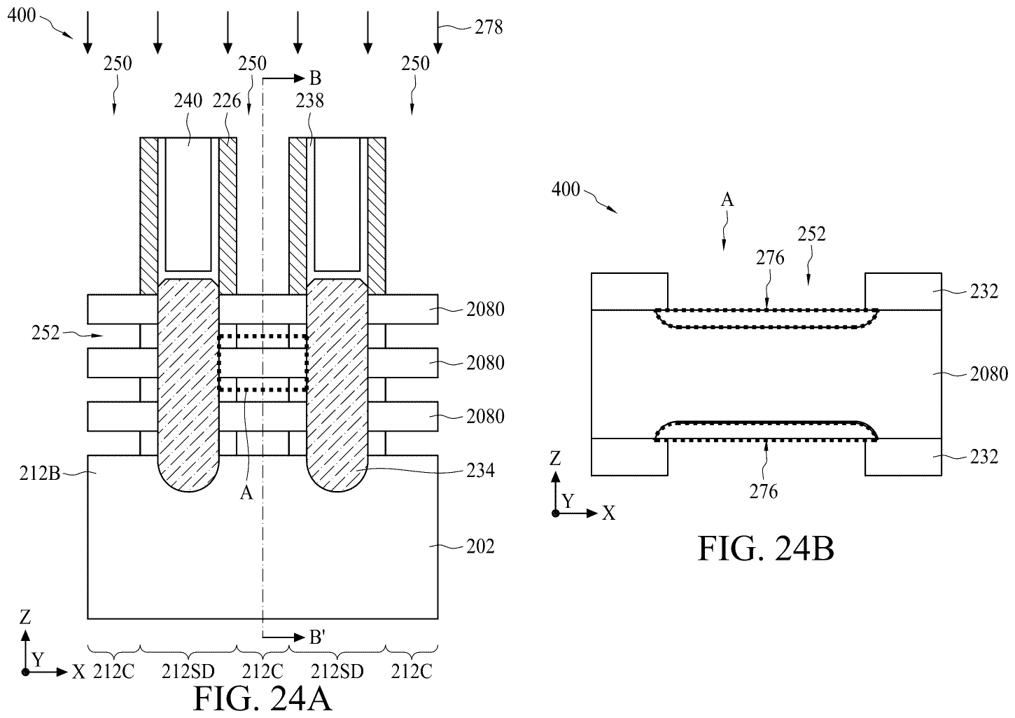

Referring to FIGS. 18 and 24A-24B, after block 118, method 300 includes a block 334 where the dummy layer 272 is removed to form openings 252. A fragmentary cross-sectional view of the structure 400 along line B-B in FIG. 24A is similar to FIG. 13. After the removal of the dummy gate stack 220, sidewalls of the channel members 2080 and the dummy layer 272 in the channel region 212C are exposed. Referring to FIGS. 24A-24B, a fourth etch process 278 may be performed to selectively remove the dummy layer 272 in the channel region 212C. For example, a selective wet etch process or a selective dry etch process may be performed to remove the dummy layer 272. An example selective wet etch process may include use of diluted hydrofluoric acid (DHF) or a mixture of hydrofluoric acid (HF) and, ammonium fluoride (NH₄F). A ratio of HF to water (H₂O) in the etchant of the selective wet etch process may be about 0.1 to about 0.01. An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. In some embodiments, the etchant of the selective dry etch process includes HF and NH₃, and a ratio of HF to NH₃ is about 0.3 to about 3. In some embodiments, the etchant of the etching process 278 is more acidic than the etchant of the etching process 258. The etchant may be dissociated into radicals to enhance its reactivity. The fourth etch process 278 may include an annealing process above about 100° C. A temperature of the fourth etching process 278 may be lower than a temperature of the third etching process 258. In some embodiments, before the etching starts, the structure 400 undergoes an incubation process where a pre-etchant stays in contact with the structure 400 for an incubation time duration. The pre-etchant may include HF and NH₃. In some embodiments, the fourth etching process 278 etches the material of the dummy layer 272 (e.g., silicon oxide, silicon nitride) at a fifth rate R5 and etches the material of the channel members 2080 (e.g., silicon) at a sixth rate R6. R5 is greater than R6. A ratio of the R5 to R6 (or etch selectivity of the material of the dummy layer 272 to the material of the channel layers 2080) is greater than about 5:1, alternatively about 10:1 to about 50:1 After the selective removal of the dummy layer 272, the channel members 2080 in the channel region 212C are once again exposed as shown in FIGS. 24A-24B and 13.

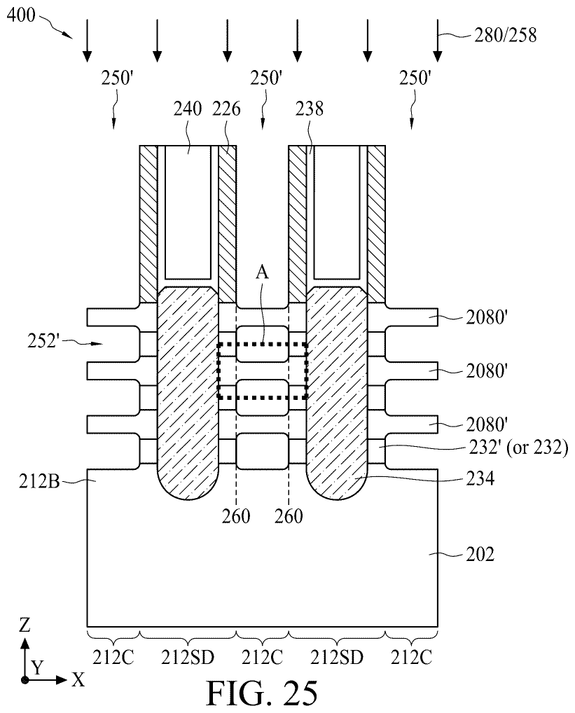

Referring to FIGS. 18 and 25, method 300 includes a block 336 where a portion of the channel members 2080 and the base fin structure 212B, and optionally a portion of the inner spacer features 232 are removed to enlarge the gate trench 250 and the openings 252, thereby forming the enlarged gate trench 250′ and the enlarged openings 252′. Compared to operations at block 122, operations at block 336 may include a fifth etching process 280 instead of the second etching process 256 to remove the portion of the channel members 2080. Upon completion of the fifth etching process 280, the structure 400 in FIG. 25 may be similar to the structure 200 in FIGS. 14-15E. Enlarged views of a portion A in FIG. 25 may be similar to FIGS. 15A-15E except that H1 may be about 5 nm to about 10 nm. In some embodiments (e.g, FIGS. 15A-15C and 15E), similar to block 122, operations at block 336 further includes the third etching process 258 to remove the portion of the inner spacer features 232 as described above. In some other embodiments, such as depicted in FIG. 15D, the third etching process 258 is omitted.

The fifth etching process 280 trim (i.e., remove a portion of) the channel members 2080 exposed in the gate trench 250 and the openings 252. The etching process 280 may include selective dry etch, selective wet etch, or other selective etch processes. In some embodiments, the etching process 280 may be a selective isotropic dry etching process that selectively etches a portion of the channel members 2080 and the base fin structure 212B. In some embodiments, the portion of the channel members 2080 and the base fin structure 212B includes the interdiffusion regions 276 and optionally additional portions that includes essentially (e.g., greater than 95%) components of the channel members 2080 (e.g., silicon). In an embodiment, the selective dry etching process may include use of HF and a nitrogen-based etchant, such as NH₃. The etchant may be dissociated into radicals to enhance its reactivity. The fifth etch process 280 may include an annealing process above about 100° C .

Various etching parameters can be tuned to achieve the target profiles of the channel members 2080 as described with respect to FIGS. 15A-15E, such as etchant composition, etching temperature, etching solution concentration, etching time, etching pressure, source power, RF bias voltage, RF bias power, etchant flow rate, byproduct evaporation rate, other suitable etching parameters, or combinations thereof. For example, an etchant is selected for the etching process 280 that etches the material of the dummy layer 272 (e.g., silicon oxide, silicon nitride) at a seventh rate R7 and etches the material of the channel members 2080 (e.g., silicon) at an eighth rate R8. A ratio of the R7 to R8 (or etch selectivity of the material of the dummy layer 272 to the material of the channel layers 2080) is about 3:1 to about 1:3.

In some embodiments, the etching process 280 is different from the etching process 278 and the etching process 258. The etchant of the etching process 280 may be different from the etchant of the etching process 278 and the etchant of the etching process 258 in composition. For example, for dry etch processes, a ratio of HF to NH₃ in the etchant of the etching process 280 may be greater than the ratio of HF to NH₃ in the etchant of the etching process 278. For wet etch processes, a ratio of HF to H₂O in the etchant of the etching process 280 may be greater than the ratio of HF to H₂O in the etchant of the etching process 278. For the dummy layer 272 having different compositions, operating conditions (e.g., the ratio of HF to H₂O) may be different from described above. A temperature of the etching process 280 may be higher than a temperature of the etching process 278 and the temperature of the etching process 258. A pressure of the etching process 280 may be lower than a pressure of the etching process 278 and lower than the pressure of the etching process 258. In some embodiments, the ratio of R7 to R8 is less than the ratio of R5 to R6. In some embodiments where an incubation process is included in the etching process 280, the pre-etchant may include HF and NH₃. A ratio of HF to NH₃ in the pre-etchant of the etching process 280 may be greater than the ratio of HF to NH₃ in the pre-etchant of the etching process 278. In some embodiments, evaporation rate of byproducts (e.g., ammonium fluorosilicate) in the etching process 280 is greater than evaporation rate of byproducts (e.g., ammonium fluorosilicate) in the etching process 278. In some embodiments, the etching process 278, the etching process 280, and the etching process 258 are performed at different chambers. The etchin ( )g process 280 may reduce surface roughness of the channel members 2080. In other words, the surfaces of the channel members 2080 upon completion of the etching process 280 are smoother than the surfaces of the channel members 2080 upon completion of the etching process 278.

Benefits of the etching process 280 is similar to the benefits of the etching process 256 as described above, except that instead of the interdiffusion regions 236, the interdiffusion regions 276 are removed, Vt shift caused by impurities in the interdiffusion regions 276 are mitigated. H1 of the structure 400 may be greater than H1 of the structure 200, thus channel resistance of the channel members 2080 of the structure 400 may be less than that of the structure 200.

Referring to FIG. 18, after bock 336, method 300 proceeds to block 124 as described above in method 100. Resulted structure 400 may be similar to the structure 200 in FIGS. 16-17F. The semiconductor device 400 may undergo further processing to form various features and regions known in the art similar as described above with respect to the structure 200.

One of ordinary skill may recognize although FIGS. 2-17F and 19-25 illustrate GAA devices as embodiments, other examples of semiconductor devices may benefit from aspects of the present disclosure. For example, aspects of the present disclosure may also apply to implementation based on fork-sheet devices, complementary FET (CFET) devices, and the like. CFET devices include a first transistor of a first conductivity type (e.g., n-type or p-type) vertically stacked over a second transistor having an opposite conductivity type. In some examples, GAA transistors may be used to implement CFET devices.

Although not intended to be limiting, one or more embodiments of the present disclosure provide many benefits to a semiconductor device. For example, the present disclosure form channel members having uniform profiles and inner portions of a gate structure having uniform profiles by performing a series of etching processes to the channel members and the inner spacer features. In addition, interdiffusion regions in the channel members are removed, and effective source/drain electrical field is increased. Thus, the overall performance of the semiconductor device may be improved.

In one exemplary aspect, the present disclosure is directed to a method. The method includes forming a fin-shaped structure disposed over a substrate, the fin-shaped structure including a stack of alternating channel layers and sacrificial layers, forming a dummy gate structure over a channel region of the fin-shaped structure, forming a source/drain recess in a source/drain region of the fin-shaped structure, selectively and partially recessing the sacrificial layers to form inner spacer recesses among the channel layers, forming inner spacer features in the inner spacer recesses, forming a source/drain feature in the source/drain recess, removing the dummy gate structure to form a gate trench, selectively removing the sacrificial layers to form an opening, performing an etching process to remove a portion of the channel layers and a portion of the inner spacer features, thereby enlarging the gate trench and the opening, and forming a gate structure in the enlarged gate trench and the enlarged opening.

In some embodiments, performing the etching process includes performing a first etching process to remove the portion of the channel layers, thereby reducing a height of a middle portion of the channel layers, and performing a second etching process to remove the portion of the inner spacer features. In some embodiments, selectively removing the sacrificial layers is at a first temperature and a first pressure, and the first etching process is at a second temperature and a second pressure, the second temperature higher than the first temperature and the second pressure lower than the first pressure. In some embodiments, selectively removing the sacrificial layers has a first etch selectivity of the channel layers to the sacrificial layers, the first etching process has a second etch selectivity of the channel layers to the sacrificial layers, the second etch selectivity less than the first etch selectivity. In some embodiments, after performing the etching process, the channel layers each include two end portions and a middle portion connecting the two end portions, the middle portion has a first height and the two end portions each have a second height greater than the first height. In some embodiments, a topmost channel layer is symmetric with respect to a horizontal center line of the topmost channel layer. In some embodiments, the portion of the channel layers includes components diffused from the sacrificial layers. In some embodiments, the gate structure includes a top portion in the enlarged gate trench and inner portions in the enlarged opening, the inner spacer features are disposed between the inner portions and the source/drain feature, each of the inner portions of the gate structure has an intersection point with an adjacent inner spacer feature of the inner spacer features and an adjacent channel layer of the channel layers, a virtual line through the intersection points aligns with a sidewall of the top portion of the gate structure.

In another exemplary aspect, the present disclosure is directed to a method. The method includes providing a structure. The structure includes a stack of alternating channel layers and interposer layers, a dummy gate structure disposed over the stack, and a source/drain trench adjacent to the dummy gate structure and exposing sidewalls of the stack. The method further includes selectively and partially recessing the interposer layers to form inner spacer recesses among the channel layers, forming inner spacer features in the inner spacer recesses, forming a source/drain feature in the source/drain trench, removing the dummy gate structure, performing a first etching process to remove the interposer layers, performing a second etching process to remove a portion of the channel layers, performing a third etching process to remove a portion of the inner spacer features, and forming a gate structure to wrap around the channel layers.

In some embodiments, the interposer layers include semiconductor layers or dielectric layers. In some embodiments, the first etching process has a first etch selectivity of the interposer layers to the channel layers, the second etching process has a second etch selectivity of the interposer layers to the channel layers, the second etch selectivity less than the first etch selectivity. In some embodiments, the first etching process is at a first temperature, the second etching process is at a second temperature higher than the first temperature. In some embodiments, the first etching process includes use of a first etchant, the second etching process includes use of a second etchant, and the third etching process includes use of a third etchant, the first etchant, the second etchant, and the third etchant are different in composition. In some embodiments, in a cross-sectional view including the gate structure, the inner spacer features, and the source/drain feature, the gate structure includes inner portions interleaving with the channel layers and a top portion disposed over the inner portions, the inner spacer features are disposed between the inner portions and the source/drain feature, each inner portion has a top surface including a straight middle portion and two curved end portions, one of the two curved end portions has an intersection point with a top surface of an adjacent inner spacer feature of the inner spacer features, a virtual line through the intersection points aligns with a sidewall of the top portion of the gate structure. In some embodiments, a portion of the top surface and a bottom surface of the adjacent inner spacer feature interface with the each inner portion. In some embodiments, the interposer layers include silicon germanium, the portion of the channel layers includes germanium diffused from the interposer layers, the first etching process is at a first temperature, and the third etching process is at a third temperature higher than the first temperature.

In yet another exemplary aspect, the present disclosure is directed to a semiconductor structure. The semiconductor structure includes a stack of channel layers, a metal gate structure including inner portions interleaving with the channel layers of the stack and a top portion disposed over the inner portions, a gate spacer layer disposed along a sidewall of the top portion of the metal gate structure, a source/drain feature disposed adjacent to the gate spacer layer and connected to the channel layers, and inner spacer features disposed between the inner portions of the metal gate structure and the source/drain feature. In a cross-sectional view including the inner spacer features, the metal gate structure, and the source/drain feature, the inner spacer features each have a top surface, a bottom surface, and a sidewall each interfacing with the inner portions, and in the cross-sectional view, a virtual line through intersection points of the inner portions of the metal gate structure, the channel layers, and the inner spacer features aligns with the sidewall of the top portion of the metal gate structure.

In some embodiments, the cross-sectional view is a first cross-sectional view, in a second cross-sectional view perpendicular to the first cross-sectional view and including the inner spacer features, the metal gate structure, and the channel layers, the metal gate structure wraps around each of the inner spacer features and each of the channel layers. In some embodiments, the channel layers each include two enlarged end portions, a middle portion between the two enlarged end portions, and two joint portions, the two enlarged end portions have a greater height than the middle portion, each of the two joint portions connects the middle portion and one of the two enlarged end portions, each of the two joint portions has a curved top surface and a curved bottom surface. In some embodiments, in the cross-sectional view, the inner spacer features extend into the inner portions of the metal gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin-shaped structure disposed over a substrate, the fin-shaped structure including a stack of alternating channel layers and sacrificial layers;
forming a dummy gate structure over a channel region of the fin-shaped structure;
forming a source/drain recess in a source/drain region of the fin-shaped structure;
selectively and partially recessing the sacrificial layers to form inner spacer recesses among the channel layers;
forming inner spacer features in the inner spacer recesses;
forming a source/drain feature in the source/drain recess;
removing the dummy gate structure to form a gate trench;
selectively removing the sacrificial layers to form an opening;
performing an etching process to remove a portion of the channel layers and a portion of the inner spacer features, thereby enlarging the gate trench and the opening; and
forming a gate structure in the enlarged gate trench and the enlarged opening.

2. The method of claim 1, wherein performing the etching process includes:
performing a first etching process to remove the portion of the channel layers, thereby reducing a height of a middle portion of the channel layers; and
performing a second etching process to remove the portion of the inner spacer features.

3. The method of claim 2, wherein selectively removing the sacrificial layers is at a first temperature and a first pressure, and
wherein the first etching process is at a second temperature and a second pressure, the second temperature higher than the first temperature and the second pressure lower than the first pressure.

4. The method of claim 2, wherein selectively removing the sacrificial layers has a first etch selectivity of the channel layers to the sacrificial layers,
wherein the first etching process has a second etch selectivity of the channel layers to the sacrificial layers, the second etch selectivity less than the first etch selectivity.

5. The method of claim 1, wherein after performing the etching process, the channel layers each include two end portions and a middle portion connecting the two end portions,
wherein the middle portion has a first height and the two end portions each have a second height greater than the first height.

6. The method of claim 5, wherein a topmost channel layer is symmetric with respect to a horizontal center line of the topmost channel layer.

7. The method of claim 1, wherein the portion of the channel layers includes components diffused from the sacrificial layers.

8. The method of claim 1, wherein the gate structure includes a top portion in the enlarged gate trench and inner portions in the enlarged opening,
wherein the inner spacer features are disposed between the inner portions and the source/drain feature,
wherein each of the inner portions of the gate structure has an intersection point with an adjacent inner spacer feature of the inner spacer features and an adjacent channel layer of the channel layers,
wherein a virtual line through the intersection points aligns with a sidewall of the top portion of the gate structure.

9. A method, comprising:
providing a structure including:
a stack of alternating channel layers and interposer layers,
a dummy gate structure disposed over the stack, and
a source/drain trench adjacent to the dummy gate structure and exposing sidewalls of the stack;
selectively and partially recessing the interposer layers to form inner spacer recesses among the channel layers;
forming inner spacer features in the inner spacer recesses;
forming a source/drain feature in the source/drain trench;
removing the dummy gate structure;
performing a first etching process to remove the interposer layers;
performing a second etching process to remove a portion of the channel layers;
performing a third etching process to remove a portion of the inner spacer features; and
forming a gate structure to wrap around the channel layers.

10. The method of claim 9, wherein the interposer layers include semiconductor layers or dielectric layers.

11. The method of claim 9, wherein the first etching process has a first etch selectivity of the interposer layers to the channel layers, the second etching process has a second etch selectivity of the interposer layers to the channel layers, the second etch selectivity less than the first etch selectivity.

12. The method of claim 9, wherein the first etching process is at a first temperature, the second etching process is at a second temperature greater than the first temperature.

13. The method of claim 9, wherein the first etching process includes use of a first etchant, the second etching process includes use of a second etchant, and the third etching process includes use of a third etchant,
wherein the first etchant, the second etchant, and the third etchant are different in composition.

14. The method of claim 9, wherein in a cross-sectional view including the gate structure, the inner spacer features, and the source/drain feature, the gate structure includes inner portions interleaving with the channel layers and a top portion disposed over the inner portions,
wherein the inner spacer features are disposed between the inner portions and the source/drain feature,
wherein each inner portion has a top surface including a straight middle portion and two curved end portions,
wherein one of the two curved end portions has an intersection point with a top surface of an adjacent inner spacer feature of the inner spacer features,
wherein a virtual line through the intersection points aligns with a sidewall of the top portion of the gate structure.

15. The method of claim 14, wherein a portion of the top surface and a bottom surface of the adjacent inner spacer feature interface with the each inner portion.

16. The method of claim 9, wherein the interposer layers include silicon germanium,
wherein the portion of the channel layers includes germanium diffused from the interposer layers,
wherein the first etching process is at a first temperature, and
wherein the third etching process is at a third temperature higher than the first temperature.

17. A semiconductor structure, comprising:
a stack of channel layers;
a metal gate structure including inner portions interleaving with the channel layers of the stack and a top portion disposed over the inner portions;
a gate spacer layer disposed along a sidewall of the top portion of the metal gate structure;
a source/drain feature disposed adjacent to the gate spacer layer and connected to the channel layers; and
inner spacer features disposed between the inner portions of the metal gate structure and the source/drain feature,
wherein in a cross-sectional view including the inner spacer features, the metal gate structure, and the source/drain feature, the inner spacer features each have a top surface, a bottom surface, and a sidewall each interfacing with the inner portions, and
wherein in the cross-sectional view, a virtual line through intersection points of the inner portions of the metal gate structure, the channel layers, and the inner spacer features aligns with the sidewall of the top portion of the metal gate structure.

18. The semiconductor structure of claim 17, wherein the cross-sectional view is a first cross-sectional view,
wherein in a second cross-sectional view perpendicular to the first cross-sectional view and including the inner spacer features, the metal gate structure, and the channel layers, the metal gate structure wraps around each of the inner spacer features and each of the channel layers.

19. The semiconductor structure of claim 17, wherein the channel layers each include two enlarged end portions, a middle portion between the two enlarged end portions, and two joint portions,
wherein the two enlarged end portions have a greater height than the middle portion,
wherein each of the two joint portions connects the middle portion and one of the two enlarged end portions,
wherein each of the two joint portions has a curved top surface and a curved bottom surface.

20. The semiconductor structure of claim 17, wherein in the cross-sectional view, the inner spacer features extend into the inner portions of the metal gate structure.
